(19) United States
(12) Patent Application Publication
(10) Pub. No.: US 2016/0201191 A1
(43) Pub. Date: Jul. 14, 2016

(54) VOLTAGE-RESISTANT, ELECTRICALLY INSULATING COATINGS

(71) Applicant: NMI Naturwissenschaftliches und Medizinisches Institut an der Universitaet Tuebingen, Reutlingen (DE)

(72) Inventors: Volker Bucher, Rottweil (DE); Wilfried Nisch, Tuebingen (DE); Marcel Roeder, Remshalden (DE)

(73) Assignee: NMI Naturwissenschaftliches und Medizinisches Institut an der Universitaet Tuebingen

(21) Appl. No.: 15/074,680

(22) Filed: Mar. 18, 2016

Related U.S. Application Data
(63) Continuation of application No. PCT/EP2014/069780, filed on Sep. 17, 2014.

(30) Foreign Application Priority Data
Sep. 20, 2013 (DE) 102013110394.4

(51) Int. Cl. C23C 16/26; C23C 16/455; B05D 1/00; C23C 16/40; C23C 16/34

(52) U.S. Cl. CPC C23C 16/26; C23C 16/403; C23C 16/401; C23C 16/345; C23C 16/405; B05D 1/60; C23C 16/45525

(57) ABSTRACT

A device has a surface with an electrically insulating coating, said coating having a bottom layer arrangement having a thickness of at most 50 μm, and a top layer arrangement having a thickness of at most 50 μm, the bottom layer arrangement consisting of a hard voltage-resistant material and the top layer arrangement consisting of a gap-penetrative voltage-resistant material.

This is a continuation application of co-pending International Patent Application PCT/EP2014/069780, filed Sep. 17, 2014, and designating the United States, which was published in German as WO 2015/040048 A1, and claims priority to German Patent Application DE 10 2013 110 394.4, filed Sep. 20, 2013, which is incorporated herein by reference.

### BACKGROUND

The present invention relates to a device having a surface provided on which there is an electrically insulating coating which is voltage-resistant preferably at least up to 1000 volts, and also to a method for producing such coatings.

Voltage-resistant, electrically insulating surface coatings are needed in many areas of industry. They not only protect the surfaces on which the coating is applied from direct contact with electrical voltages, but also prevent electrical voltages applied over the coatings from “breaking down” onto the surfaces.

Failure of such insulating coats is generally referred to as voltage breakdown.

For these coatings to be able to exert their protective function durably, they are to be mechanically robust, more particularly scratch-resistant, abrasion-resistant, and wear-resistant, so responding to the required cleaning measures and/or to service by not being gradually worn away or suffering damage that adversely affects the voltage proof.

The reason is that even minute defects in the coating, such as cracks, holes, or indentations, lead to a loss of continued voltage resistance locally within the area of this surface damage.

Coatings of this kind find application in and on electrically operated apparatus and/or articles which come into contact with such apparatus. Their purpose therein is to protect the apparatus, the articles, and those persons or animals coming into contact with such apparatus and articles from contact with electrical voltages and/or currents.

A “device” for the purposes of the present invention is therefore an article of any kind that has an external or internal surface that has been or is being provided with an electrically insulating coating.

“Voltage-resistant, electrically insulating coatings” are also referred to below for short as “insulation coats”.

Coatings of this kind are particularly important in electrosurgery, where they serve to protect the patient and the surgeon. Electrosurgery is an important surgical technique which involves, for example, the stanching of bleeds and the cutting or sealing of tissue using high-frequency alternating current.

Electrosurgical instruments are tested in accordance with the German Industrial Standard 60601-2-2. The insulation coats used are required by that standard to withstand voltages of more than 1000 volts.

Currently in use as electrical insulation coats mostly are plastics and ceramics. One frequently encountered coating consists of polyamide 11 or 12 (Rilsan®), which is applied to the instruments by powder coating. Polyamide is a thermoplastic polymer produced by polycondensation from dicarboxylic acid and diamines.

Other materials frequently used are the high-performance polymers poly-etheretherketone (PEEK) and polytetrafluoroethylene (PTFE, Teflon®). Another method for insulating electrosurgical instruments is the use of shrink-on sleeves of nylon or polyimide.

The advantage of plastics as insulation material is a high resistance toward shock and impact stresses. Problems arise, however, on high thermal exposure of the plastics.

As well as ensuring the required voltage resistance of preferably at least 1000 volts, the coatings are required to be biocompatible, repeatedly sterilizable, and mechanically robust.

The known insulation coats which meet these requirements generally all have a minimum thickness of 0.15 mm, with insulation coats having a minimum thickness of 0.25 mm being in frequent use.

Surgery today is concerned with being able to carry out operations with smaller and smaller interventions in order to minimize trauma to the patient. New minimally invasive surgical interventions in the areas of neurosurgery, urology, surgical cardiology, and gynecology, moreover, necessitate miniaturized instruments so that operations can be performed in areas that are difficult to reach.

The contribution of the known insulation coats to the diameter of an electro surgical instrument, however, is generally twice 0.25 mm, in other words about 0.5 mm, which therefore opposes any further miniaturization of the instruments.

Consequently there is a need for thinner insulation coats having properties comparable with those of the known coatings.

### SUMMARY

It is among others one object of the present invention, to provide a new coating of the type specified at the outset, but having a thickness of less than 0.1 mm while exhibiting electrical and mechanical properties comparable with those of the known coatings.

This and other objects are achieved in accordance with the invention in that the coating is multilayer in form, comprising at least one bottom layer having a thickness of at most 50 μm, and comprising a top layer, applied on the bottom layer, having a thickness of at most 50 μm, the bottom layer consisting of a hard voltage-resistant material and the top layer consisting of a gap-penetrative voltage-resistant material.

A “hard voltage-resistant material” in the context of the present invention refers to a material which at a thickness of less than 50 μm has a theoretical voltage resistance of at least 1000 volts and which has scratch and wear resistance like that of DLC (diamondlike carbon), which, however, on deposition on the surface, as a result of condensation effects, particle exposure or coat stress cracks, forms defects in the form of blind holes and/or holes providing passage down to the surface, these holes adversely affecting the voltage resistance.

Examples of hard voltage-resistant materials that can be used in the context of the present invention are—alongside Al₂O₃, DLC, and SiOₓ—SiNX, Ta₂O₅, HfO₂, TiO₂, and ZrO₂, as well.

A “gap-penetrative voltage-resistant material” refers in the context of the present invention to a material which when deposited on the layer of hard material fills up the defects that are present in the hard material, and which is preferably sterilizable, and which at a thickness corresponding to that of the hard voltage-resistant material has a theoretical voltage resistance of at least 1000 volts but on account of its ability to penetrate gaps is mechanically softer than DLC or SiOₓ.

Examples of gap-penetrative voltage-resistant materials which can be used in the context of the present invention are, generally, soft polymers such as parylene or hard materials applied by the specific Atomic Layer Deposition process (ALD).

A “theoretical voltage resistance” refers in the context of the present invention to the voltage resistance which is achieved under perfect conditions in a mechanically intact layer of the corresponding thickness.

The inventors, therefore, have chosen two coating materials which taken per se are not suitable for the coating of electrosurgical instruments and combined them to form a multilayer coating in which the mechanical defects in the bottom layer are filled up by the gap-penetrative top layer. The voltage resistance here is determined primarily by the material and thickness of the bottom layer.

The multilayer coating of the invention is sterilizable on account of the properties of the top layer. The fact that the top layer is possibly not as abrasion-resistant as the bottom one may result in the top layer being wholly or partly worn away over time. The sealing of the defects in the bottom layer is nevertheless retained, and so the voltage resistance of the new coating is nevertheless retained on account of the likewise voltage-resistant filling material.

Because the material of the top layer is surrounded in the defects by the harder material of the bottom layer, this filling material is not removed further, even after complete removal of the top layer, in the event of further stresses due to sterilizing and mechanical loads.

If the thickness of the bottom layer is sufficiently great for a layer of equal thickness of the top material to have the required voltage resistance, then the voltage resistance is retained even after wearing of the top layer, since the defects in the bottom layer have been filled with the material of the top layer.

The coating of the invention has a thickness of 100 μm or less, thus permitting further-miniaturized electrosurgical instruments. In one embodiment, the bottom and the top layers each may have a thickness of about 5 μm. In other embodiments, the bottom layer may have a thickness of about 10 μm to 16 μm and the top layer may have a thickness of about 8 μm to 10 μm.

In view of the above, the present invention also relates to a method for producing a voltage-resistant, electrically insulating coating on a surface of a device, wherein there are deposited in succession on the surface at least one bottom layer of a hard voltage-resistant material in a thickness of at most 50 μm and a top layer of a gap-penetrative voltage-resistant material in a thickness of at most 50 μm

In one embodiment, the bottom layer comprises a layer of DLC and/or SiOₓ, and is preferably constructed at least of two layers.

DLC and SiOₓ are two materials which are particularly highly suitable for the bottom layer.

The bottom layer may comprise a layer of hard DLC and a layer of soft DLC, the bottom layer in one embodiment comprising at least three layers of hard DLC and three layers of soft DLC, with the layers of hard and soft DLC being in alternation, and the lower of the layers may consist of hard DLC.

By this a multilayer DLC layer adhering well to the surface is created, the thickness of this DLC layer being one which cannot be produced for a single layer without substantial defects and which is such that a layer of the material of the top layer in the same thickness has the required voltage resistance.

The inventors have found, however, that even a DLC layer with this multilayer construction still has defects, resulting in the voltage resistance of this layer failing to achieve the required levels. In other words, the defects in the different layers are generally not distributed in such a way that they do not overlap. In accordance with the invention, therefore, even a multilayer bottom DLC layer has a top layer of crack-penetrative material applied to it.

The deposition of hard and soft DLC layers in alternation is described for example in Knoblauch et al., “Tribological properties of bias voltage modulated a-C:H nanoscaled multilayers”, in Surface and Coatings Technology, 94-95 (1997), pages 521-524.

The authors describe the possibility, using plasma-assisted chemical vapor deposition (PACVD), of depositing DLC layers whose hardness is dependent on the bias voltage.

A “layer of hard DLC” refers to a DLC layer which is deposited with a bias voltage that is at least twice as great as the bias voltage with which the “layer of soft DLC” is deposited. The terms “hard” and “soft” should therefore be understood as relative terms rather than as absolute terms.

In one embodiment, each layer of hard or soft DLC comprises a thickness of between 0.1 and 1.5, preferably between 0.3 and 1 μm.

DLC layers of this thickness can be deposited reliably and with effective adhesion on customary surfaces and on one another.

The top layer may consist of a soft polymer, more particularly of parylene, and may comprise a thickness of between 2 and 10 μm.

Parylenes, more particularly parylene C and parylene F, are two materials which are particularly highly suitable for the top layer and which reliably fill out defects in the bottom layer even when the bottom layer has a thickness of up to 20 μm, preferably 10 μm, and is of multilayer form.

The top layer may comprise a layer of a hard voltage-resistant material, more particularly of Al₂O₃, SiOₓ, SiNₓ, Ta₂O₅, HfO₂, TiO₂, or ZrO₂, produced by an ALD process, wherein the top layer may comprise a thickness of less than 500 nm.

When hard materials are applied to substrates using the customary processes for thin-film generation such as PVD (physical vapor deposition) or PACVD (plasma-assisted chemical vapor deposition), numerous local defects are apparent, such as pinholes or stress cracks. With ALD, a modified CVD (chemical vapor deposition) process, the same hard materials can indeed be applied in pinhole-free and stress crack-free form, but not economically in sufficient thickness, in the region of several μm, for example.

However, a thin ALD layer is able, just like parylene, to seal relatively small defects, since being highly gap-penetrative. By combining the coating techniques it is possible for greater thicknesses to be produced economically.

The inventors have found that thin ALD layers of up to 500 nm are capable of completely closing the defects in the bottom layer in such a way that the isolation coat thus constructed has the required voltage resistance and sufficient mechanical robustness.

The device is preferably a surgical instrument, more particularly an electrosurgical instrument.

The inventors have recognized, however, that the coating of the invention can also be used with other devices, particularly with medical implants and electrical components, in the case, for example, of layered capacitors which require thin, defect-free dielectrics in conjunction with high capacitance.

The inventors have created multilayer thin insulation coats which have a high voltage resistance of up to 1 000 V and, indeed, more than 3000 volts. In this context, various layer systems of DLC and SiOₓ with a top layer of parylene have been investigated for their firmness of adhesion, autoclavability, and voltage resistance.

DLC (diamond-like carbon) is a diamond-like material which differs from diamond only in the nature of the carbon bonding. In the case of diamond, all four valence electrons possess the same energy level, whereas with DLC only three of the four valence electrons possess the same energy level.

Hydrogen-containing DLC is distinguished from hydrogen-free DLC. Amorphous, hydrogen-containing DLC layers (a-C:H) can be prepared by plasma polymerization. One possible method for synthesizing such layers is that of plasma-assisted chemical vapor deposition (PACVD); see U.S. Pat. No. 5,512,330.

The scratch and wear resistances possessed by DLC layers are almost as good as those for diamond, and they have a high voltage resistance, very good chemical resistance, outstanding corrosion resistance, and good biocompatibility. Moreover, DLC layers have good lubricity properties with respect to metal, and good antistick effect.

It is possible to produce DLC layers which possess a relative permittivity of between 3.3 and 2.7. The voltage resistance at a layer thickness of one micrometer is about 550 V/μm. On account of these properties, DLC is used in many different areas.

In medical technology, DLC coatings are used for implants with blood contact, such as artificial heart valves, blood pumps, and stents, for example.

Moreover, the corrosion resistance and antistick effect are utilized to produce protective coats for minimally invasive surgical instruments. In other areas, DLC is used as a protective layer for highly stressed machine elements, ball bearings or gearwheels with reduced friction, razor blades, and as wear protection in the automobile sector.

DLC, however, possesses a relatively high inherent stress, which limits the layer thickness which can be produced with firm adhesion and also limits the materials on which DLC layers can be deposited. Inherent stresses are stresses which occur within a material or component without exposure to external forces. They come about during production, through plastic deformation or temperature changes, and remain in the material. Particularly in the case of materials having significantly different coefficients of thermal expansion, this leads to adhesion problems and to the development of defects which may adversely affect the voltage resistance.

US 2011/0122486 A1 discloses a coating, for implants, for example, that—relative to ions in liquid media—is electrically insulating and impervious to diffusion. The purpose of the coating is to prevent both the penetration of body fluids, endogenous substances, and ions into the implant and the emergence of constituents from the implant.

The coating comprises a multilayer top layer, which consists, for example, of alternating layers, each very thin, of diffusion-resistant and pliant a-C:H, and a bottom layer, close to the substrate, of parylene, which serves for connection to the substrate. Between the top and bottom layers and also between the bottom layer and the substrate, a transition layer is disposed in each case. The outer layer of the top layer consists of a-C:H with 20% hydrogen content. The diffusion-resistant layers are thinner in form than the pliant layers of a-C:H.

The thickness of the individual layers of the top layer and of the transition layers is between 20 and 40 nm, in one embodiment, there are 13 such layers, leading to a total top-layer thickness of 345 nm. The bottom layer here has a thickness of 500 nm.

The individual layers of the top layer are deposited in such a way that they have no ruptures or other defects which, as blind holes or through-holes (pinholes), would be detrimental to the desired impermeability to diffusion.

On account, among others, of the requirement for pinhole-free a-C:H layers, the production of the known coating is costly and inconvenient, and, moreover, the coating does not have the required voltage resistance as is needed, for example, for surgical instruments.

U.S. Pat. No. 6,926,572 B2 describes a flat, OLED-based display on whose facing or reverse side there is applied a multilayer passivation coat to protect the display from penetration by oxygen and moisture. The passivation coat comprises an otherwise unspecified sequence of organic, inorganic, and metallic layers, deposited in alternation The organic layers may comprise parylene and may have a thickness of 0.5 to several p.m. The inorganic layers may comprise SiO₂, or Al₂O₃ deposited by plasma-assisted Atomic Layer Deposition (ALD) processes, with a thickness of about 200 nm. The metallic layers may contain Al with a thickness of 100 nm.

No preferred sequence or arrangement of the individual layers is specified.

This known coating as well is costly and inconvenient to produce and, moreover, does not have the required voltage resistance of the kind needed for surgical instruments, for example.

US 2001/0052752 A1 describes a protective coat for an OLED-based display, the protective coat being intended to protect the display from penetration by oxygen and moisture. The protective coat, which is of two-layer construction, comprises an oxide layer, of Al₂O₃ or SiO₂, for example, and a polymer layer, of parylene, for example, with either the oxide layer or the parylene layer being arranged as an outer layer remote from the substrate. The oxide layer is said to be thin enough to remain optically transparent, having a thickness of less than 100 nm, for example. The thickness of the parylene layer is not explicitly stated.

This known coating as well does not have the required voltage resistance of the kind needed for surgical instruments, for example. Furthermore, the very thin oxide layer is unable to yield the mechanical properties that are required for surgical instruments, for example.

Consequently, DLC layer have so far not successfully been used for the coating of electrosurgical instruments, since high voltage resistance has not been achievable.

SiOₓ is the designation for a chemical compound formed between silicon and oxygen. In nature it occurs in both crystalline and amorphous forms. Silicon dioxide is an important material in the semiconductor and microsystems industries. There it is used primarily as an insulator and passivation coat. Silicon dioxide possesses a relative permittivity Er of 3.9. The dielectric strength at a coat thickness of 50 nm is about 1000 V/μm.

Silicon oxide layers can be produced likewise by the PECVD process. A gas mixture used for producing SiOₓ consists of hexamethyldisiloxane (HMDSO) and oxygen.

The inventors have now found that even thin layers of DLC or SiOₓ, which by themselves cannot be deposited with firm adhesion and absence of defects on the devices, can nevertheless be used for the construction of insulation coats of the invention if they are used as a bottom layer and are coated with a further layer, preferably of parylene.

The support structure for the surface of the device on which the coating is to be formed may be made of metal, more particularly of stainless steel, though it may also be a flexible foil.

The purpose of the top parylene layer here is primarily to seal any defects in the underlying insulation coats.

Parylene is the abbreviation for a group of poly(para)-xylenes which are linear, semi-crystalline, and not cross-linked. Parylene layers are deposited from the gas phase, allowing uniform deposition free from air inclusions. On the entire surface, a polymerization takes place through diffusion reactions. As a result, uniform deposition is achieved. Coverage is obtained even of edges, corners, and complex geometries. As a result of the excellent diffusion properties of the monomer, even small holes can be sealed. There are four kinds of parylene utilized industrially, possessing different properties—parylene C, parylene D, parylene N, and parylene F.

Parylene coatings can be deposited homogeneously even on irregular surface geometries, exhibit barrier effects relative to oxygen or water, for example, act as protection from corrosion, are electrically insulating with high voltage resistance, permit high mechanical deformability, and are sterilization-resistant.

It is possible to produce parylene layers which possess a relative permittivity of between 3 and 2. At a layer thickness of one micrometer, the dielectric strength is about 220 V/μm.

Parylene is therefore already used in the coating of biomedical devices such as cardiac pacemakers, stents, and flexible neural probes.

On account of their high mechanical deformability, however, parylene layers lack sufficient scratch and wear resistance, and so in spite of their high voltage resistance have so far not been used to coat electrosurgical instruments.

The inventors have recognized that the good mechanical and electrical properties of DLC layers, namely the high scratch and wear resistance and also the high voltage resistance, can be utilized in a multilayer coating if the disadvantageous properties—their lack of capacity to be deposited with sufficiently firm adhesion, free from defects, on devices—are compensated by an overlaid coating of parylene.

Conversely, the good electrical properties of parylene and its sterilizability can be utilized in a multilayer coating, despite parylene layers lacking sufficient abrasion resistance.

A combination of multilayer DLC layers and parylene F has emerged as one particularly good insulation coat. Here, in initial experiments, comparatively hard and soft DLC layers were deposited in alternation, with an overall layer thickness of 5 μm, and were subsequently covered with a layer of parylene F 5 μm thick.

Voltage resistance measurements at mains frequency (50 cps) show this insulation coat to have a voltage resistance of up to 1 000 V and hence to meet the requirement of the 60601-2-2 Standard.

In further experiments, insulation coats were deposited with, in alternation, comparatively hard and soft DLC layers, with a total layer thickness of 11 μm and 15 μm, and then covered in each case with a parylene C layer 8.6 μm thick.

Voltage resistance measurements at mains frequency (50 cps) showed the thicker of the two insulation coats to have a voltage resistance of more than 3000 V and the thinner insulation coat to have a voltage resistance of up to 2600 volts, meaning that these insulation coats also meet the requirement of the 60601-2-2 Standard.

The invention further relates to a surgical, preferably electrosurgical, instrument having a surface provided on which there is an electrically insulating coating which is multilayer in form and voltage-resistant at least up to 1000 volts and which has, mounted on the surface, a bottom layer, having a thickness of at most 50 μm, and, mounted on the bottom layer, a top layer having a thickness of at most 50 μm, the bottom layer consisting of at least two layers of a hard voltage-resistant material, and the top layer consisting of a gap-penetrative voltage-resistant material.

Further advantages are apparent from the description and the appended drawing.

It will be appreciated that the features specified above and those still to be elucidated hereinafter can be used not only in the particular combination indicated but also in other combinations or on their own, without departing from the scope of the present invention.

### BRIEF DESCRIPTION OF THE DRAWINGS

Embodiments of the invention are shown in the appended drawing and are elucidated in more detail in the description hereinafter. In the drawing

FIG. 1 shows in diagrammatic, sectional side view, a device with voltage-resistant, electrically insulating coating; and

FIG. 2 shows a representation as in FIG. 1, but with a different construction of the coating; and

FIG. 3 shows a scheme for a measurement setup used for testing the voltage resistance of a medical instrument provided with the new coating.

### DESCRIPTION OF PREFERRED EMBODIMENTS

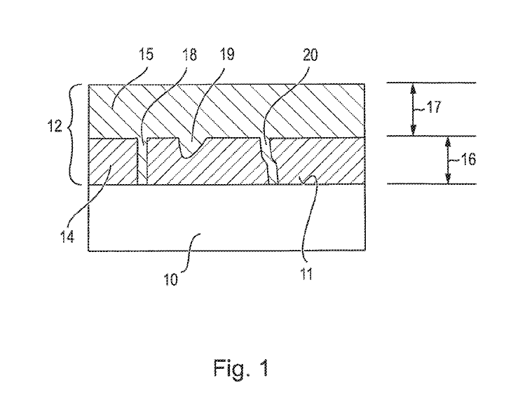

Shown in FIG. 1, in a diagrammatic side view which is not to scale, is a device 10 with a two-layer coating 12 applied on its surface 11. The device 10 is shown by way of example as a rectangle. In reality it comprises a support structure on which the coated surface 11 is located. Material used for the support structure is stainless steel, for example.

The coating 12 has a bottom layer 14 and a top layer 15. The bottom layer 14 has a thickness indicated at 16, and the top layer 15 has a thickness indicated at 17.

Shown diagrammatically in the bottom layer 14 are three defects 18, 19, and 20, which have been filled in by material of the top layer 15.

The bottom layer is a DLC layer having a thickness 16 of 1.5 μm; the top layer is a layer of parylene F with a thickness of 10 μm. This coating had a voltage resistance of 550 volts, which can be increased to more than 1000 volts by increasing the thickness 16 of the DLC layer.

For the production of the parylene layer 15, di-para-xylylene in powder form was brought in a conventional way to the gaseous state in a parylene evaporator at about 690° C. and then passed into a vacuum chamber, where at room temperature it condensed on the DLC layer and formed the parylene layer.

The DLC layers were deposited on the surfaces in a conventional way in a low-pressure PECVD system. The system consists of a vacuum chamber, a pump station, and a regulatable gas supply from which a gas mixture of hydrocarbons (tetramethylsilane and acetylene) is passed into the evacuated vacuum chamber, in which a plasma is generated via two electrodes to which high-frequency bias voltage is applied. From the plasma, the DLC layer is then deposited on the surface, with the deposition rate being dependent on the gas mixture, the pressure in the vacuum chamber, and the bias voltage.

In order to achieve a further increase in the thickness of the DLC layer 14, alternating layers of hard DLC layers and soft DLC layers were then deposited, with the layer lying directly on the surface 11 consisting of hard DLC. A total of four hard and four soft layers were deposited, leading to a thickness 16 of approximately 5 μm.

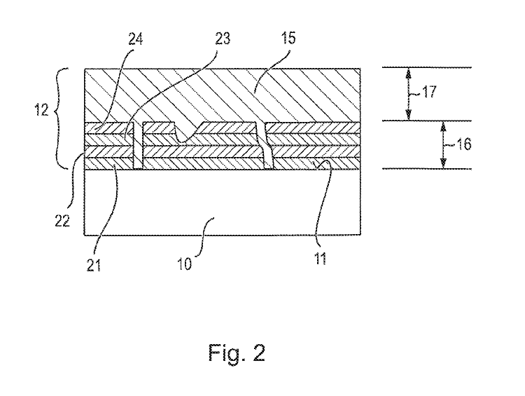

This arrangement is shown in FIG. 2, which shows, by way of example, four layers 21, 22, 23, and 24 in the layer 14; layers 21 and 23 are hard layers and layers 22 and 24 are soft layers of DLC. Layer 15 consists of parylene F and has a thickness 17 of 5 μm.

The hard DLC layers were deposited with a bias voltage of 400 volts, the soft DLC layers with a bias voltage of 100 volts, in a PAVCD system.

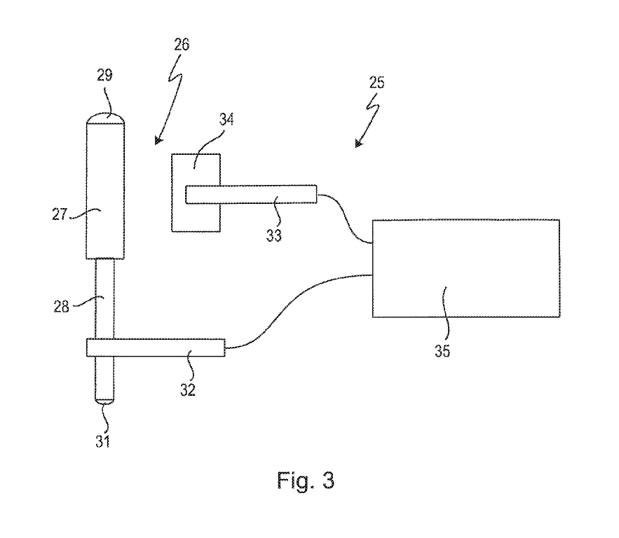

The voltage resistance of the coating 12 from FIG. 2 was up to 1100 volts in a measurement setup 25 as shown in FIG. 3.

The subject of measurement is a rod 26 which is manufactured from martensitic chromium steel with the coding 1.4021, and which represents typical geometric forms for electrosurgical instruments. It consists of a handle 27 with a shaft 28 with noticeable rounding 29 and 31 machined at the top on the handle 27 and at the bottom on the shaft 28.

The handle 27 has a length of 35 mm and a diameter of 10 mm, the shaft a length of 30 mm and a diameter of 4 mm.

The rod 26 was provided entirely with a coating 12, as described with reference to FIG. 2.

A first contact terminal 32 is connected to the shaft 28, and a second contact terminal 33 to the handle 27 via a moist sponge 34. Both contact terminals 32, 33 are connected to a testing device 35 which at mains frequency (50 cps) supplies increasing output voltages up to 5000 volts and indicates the voltage breakdown

In these experiments, voltage resistances of 1100 volts were found.

The coating 12 was visually flawless, adhered firmly to the rod 27, and showed no abrasion or wear during initial handling.

The adhesion was determined using the cross-cut test according to German Industrial Standard EN ISO 2409. In order to produce accelerated aging, the articles for measurement were stored at a temperature of 60° C. in PBS (Phosphate-Buffered Saline). The coatings, moreover, were regularly investigated with the adhesive tape removal test, in which adhesive tape was adhered to the coating and peeled off at an angle of 60°.

For the coatings described here, the resulting adhesive strengths according to this test fall into the best class GTO (very good adhesion).

Furthermore, the articles for measurement were autoclaved, in order to verify their sterilizability. For this purpose the articles for measurement were subjected to steam sterilization at 134° C. for 3 minutes.

The experiments revealed that the coatings were not adversely affected by autoclaving, and in particular the adhesive strength was not impaired as a result, as verified in subsequent adhesive tape removal testing.

1. A device comprising a surface provided with an electrically insulating coating, said coating being voltage-resistant at least up to 1000 volts, wherein
the coating comprises at least one bottom layer arrangement having a thickness of at most 50 μm, and at least one top layer arrangement having a thickness of at most 50 μm,
the bottom layer arrangement consisting of a hard voltage-resistant material and the top layer arrangement consisting of a gap-penetrative voltage-resistant material.

2. The device of claim 1, wherein the bottom layer arrangement comprises a layer of DLC.

3. The device of claim 1, wherein the bottom layer arrangement comprises a layer made from a material selected from the group consisting of Al₂O₃, SiOₓ, SiNₓ, Ta₂O₅, HfO₂, TiO₂, and ZrO₂.

4. The device of claim 1, wherein the bottom layer arrangement comprises at least two layers.

5. The device of claim 4, wherein the bottom layer arrangement comprises at least one layer of hard DLC and a least one layer of soft DLC.

6. The device of claim 5, wherein the bottom layer arrangement comprises at least three layers of hard DLC and at least three layers of soft DLC, the layers of hard and soft DLC being in alternation.

7. The device of claim 6, wherein the bottom layer arrangement comprises a bottom layer consisting of hard DLC.

8. The device of claim 5, wherein each layer of hard DLC and each layer of soft DLC comprises a thickness of between 0.1 and 1.5 μm.

9. The device of claim 5, wherein each layer of hard DLC and each layer of soft DLC comprises a thickness of between 0.3 and 1 μm.

10. The device of claim 1, wherein the top layer arrangement consists of a soft polymer.

11. The device of claim 10, wherein the top layer arrangement comprises a thickness of between 2 and 10 μm.

12. The device of claim 1, wherein the top layer arrangement comprises a layer of a hard voltage-resistant material.

13. The device of claim 12, wherein the hard voltage-resistant material is selected from the group consisting of Al₂O₃, SiOₓ, SiNₓ, Ta₂O₅, HfO₂, TiO₂, and ZrO₂, and wherein said layer within said top layer arrangement is produced by an ALD process.

14. The device of claim 13, wherein the top layer arrangement comprises a thickness of less than 500 nm.

15. The device of claim 1, selected from the group consisting of surgical instruments, medical implants, electrical components, and layered capacitors.

16. The device of claim 1, embodied as an electrosurgical instrument, wherein the bottom layer arrangement consisting of at least two layers of a hard voltage-resistant material.

17. The device of claim 16, wherein the bottom layer arrangement comprises at least three layers of hard DLC and at least three layers of soft DLC, the layers of hard and soft DLC being in alternation, the bottom layer arrangement comprising a bottom layer consisting of hard DLC.

18. The device of claim 17, wherein the top layer arrangement consists of parylene.

19. The device of claim 16, wherein the bottom layer arrangement comprises at least three layers of hard DLC and at least three layers of soft DLC, the layers of hard and soft DLC being in alternation, and wherein the top layer arrangement is constructed as one layer made of a hard voltage-resistant material, the hard voltage-resistant material being selected from the group consisting of Al₂O₃, SiOₓ, SiNₓ, Ta₂O₅, HfO₂, TiO₂, and ZrO₂, and wherein said one layer is produced by an ALD process.

20. A method for producing an electrically insulating coating which is voltage-resistant at least up to 1000 volts on a surface of a device, wherein there are deposited in succession on the surface at least one bottom layer of a hard voltage-resistant material in a thickness of at most 50 μm and a top layer of a gap-penetrative voltage-resistant material in a thickness of at most 50 μm.
